(19) United States
(12) Patent Application Publication
(10) Pub. No.: US 2026/0009126 A1
(43) Pub. Date: Jan. 8, 2026

(54) METHOD OF OPERATING FILM FORMING APPARATUS AND FILM FORMING APPARATUS

(71) Applicant: Tokyo Electron Limited, Tokyo (JP)

(72) Inventors: Yuya SASAKI, Iwate (JP); Masato KOAKUTSU, Iwate (JP); Hiroki MIURA, Iwate (JP)

(21) Appl. No.: 19/241,980

(22) Filed: Jun. 18, 2025

(30) Foreign Application Priority Data
Jul. 8, 2024 (JP) 2024-109801

(51) Int. Cl. C23C 16/44

(52) U.S. Cl. CPC C23C 16/4405

(57) ABSTRACT

A technique capable of reducing an amount of change in a depth from an upper surface of a susceptor to a mounting surface is provided. A method of operating a film forming apparatus according to one aspect of the present disclosure is a method of operating a film forming apparatus including a susceptor having a recess on a surface of the susceptor, the recess in which a substrate is mounted. The method including: (a) removing a film formed on the surface of the susceptor by supplying a cleaning gas to the susceptor with a protective member not mounted on the recess; and (b) removing the film formed on the surface of the susceptor by supplying the cleaning gas to the susceptor with the protective member mounted on the recess, wherein the (b) removing is performed after the (a) removing has been performed a first number of times.

### CROSS-REFERENCE TO RELATED APPLICATION

The present application claims priority under 35 U.S.C. § 119 to Japanese Patent Application No. 2024-109801, filed Jul. 8, 2024, the contents of which are incorporated herein by reference in their entireties.

### BACKGROUND OF THE INVENTION

### Field of the Invention

The present disclosure relates to a method of operating a film forming apparatus, and a film forming apparatus.

### Description of the Related Art

Japanese Patent Application Laid-Open Publication No. 2020-77750 discloses dry-cleaning of a susceptor in a processing chamber, including supplying a cleaning gas with a protective member mounted on a substrate mounting region of the susceptor, and removing a film deposited on the surface of the susceptor by etching. According to Japanese Patent Application Laid-Open Publication No. 2020-77750, it is possible to perform cleaning without damaging the susceptor.

### SUMMARY OF THE INVENTION

A method of operating a film forming apparatus according to one embodiment of the present disclosure is a method of operating a film forming apparatus including a susceptor having a recess on a surface of the susceptor, the recess in which a substrate is mounted, the method including: (a) removing a film formed on the surface of the susceptor by supplying a cleaning gas to the susceptor with a protective member not mounted on the recess; and (b) removing the film formed on the surface of the susceptor by supplying the cleaning gas to the susceptor with the protective member mounted on the recess, wherein the (b) removing is performed after the (a) removing has been performed a first number of times.

### BRIEF DESCRIPTION OF THE DRAWINGS

FIG. 1 is a cross-sectional view showing an example of a configuration of a film forming apparatus according to an embodiment;

FIG. 2 is an oblique view showing the configuration of the interior of a vacuum container of a film forming apparatus according to an embodiment;

FIG. 3 is a plan view showing the configuration of the interior of a vacuum container of a film forming apparatus according to an embodiment;

FIG. 4 is a cross-sectional view showing a part of a film forming apparatus according to an embodiment;

FIG. 5 is a cross-sectional view showing another part of a film forming apparatus according to an embodiment;

FIG. 6 is a cross-sectional view showing a part of a susceptor included in a film forming apparatus according to an embodiment;

FIG. 7 is a flowchart showing an example of a method of operating a film forming apparatus according to an embodiment;

FIG. 8 is a view showing change in the depth of a recess between before and after a first cleaning process;

FIG. 9 is a view showing change in the depth of a recess between before and after a second cleaning process;

FIG. 10 is a flowchart showing an example of a cleaning process; and

FIG. 11 is a flowchart showing another example of the cleaning process.

### DETAILED DESCRIPTION OF THE DISCLOSURE

Hereinafter, non-limiting exemplary embodiments of the present disclosure will be described with reference to the attached drawings. In all of the attached drawings, the same or corresponding members or parts will be denoted by the same or corresponding reference numerals and duplicate descriptions will be omitted.

### [Film Forming Apparatus]

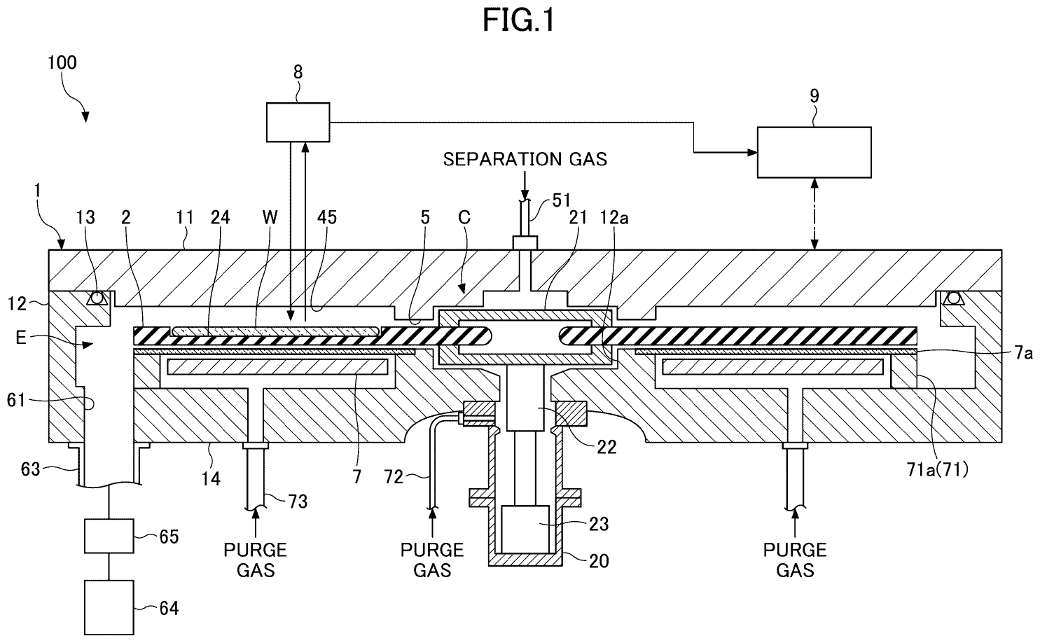

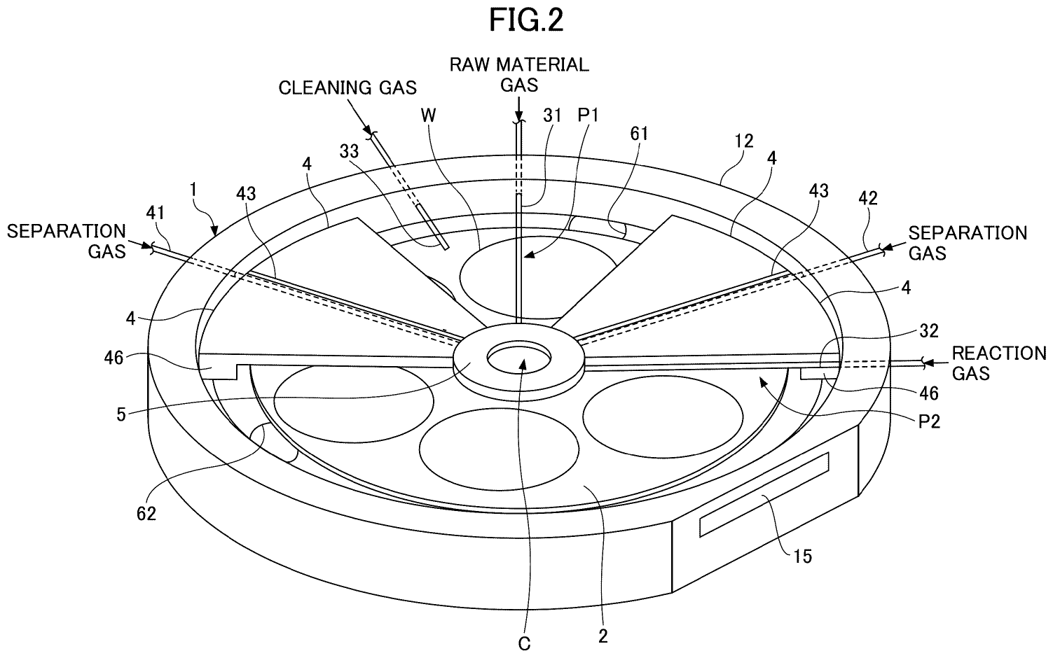

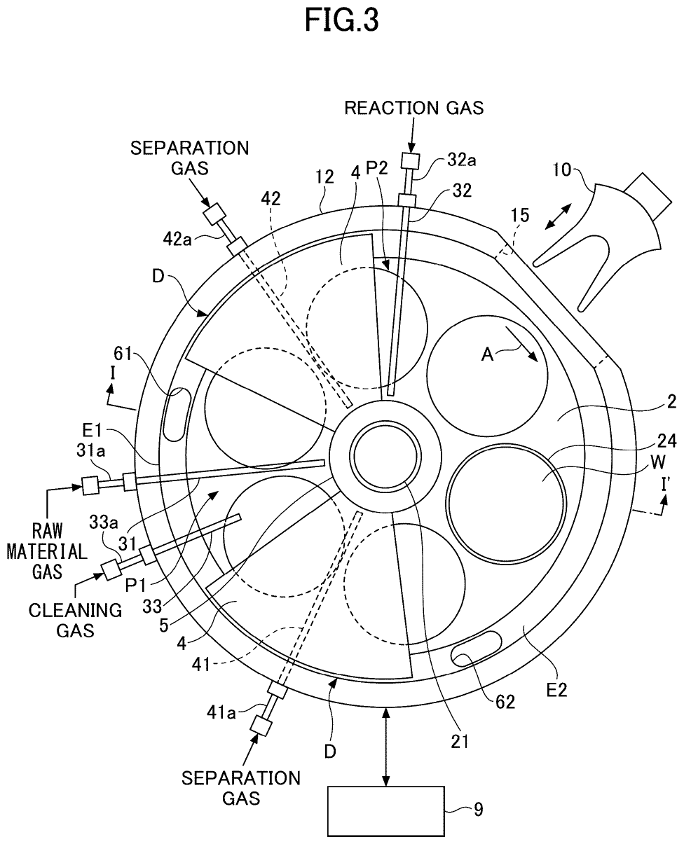

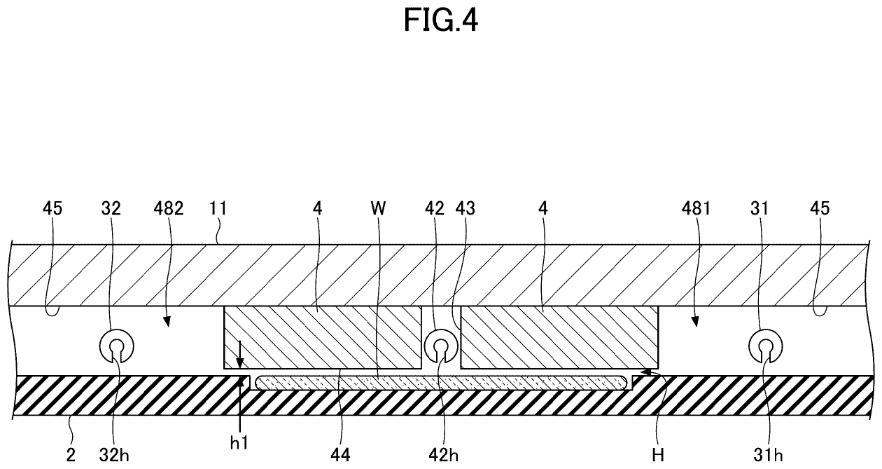

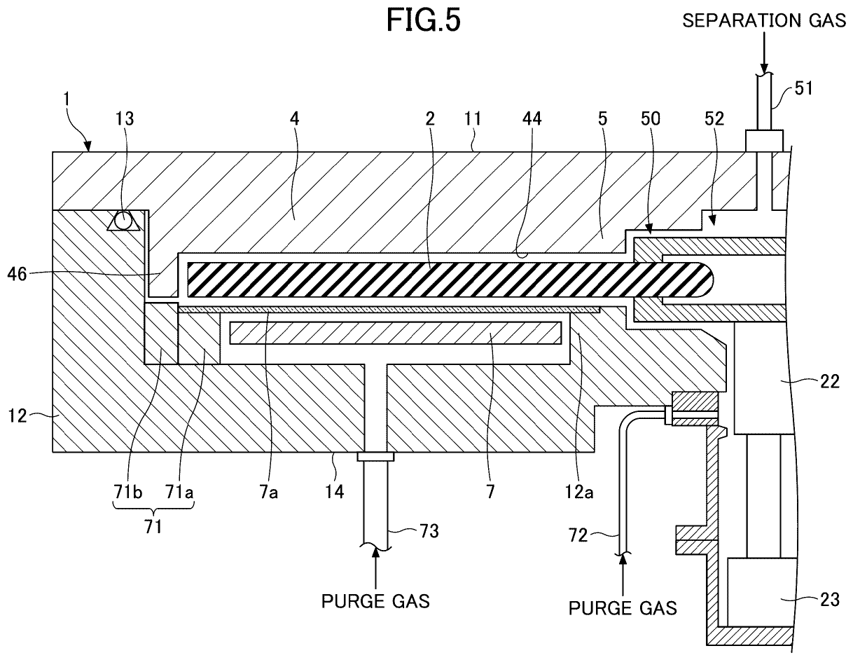

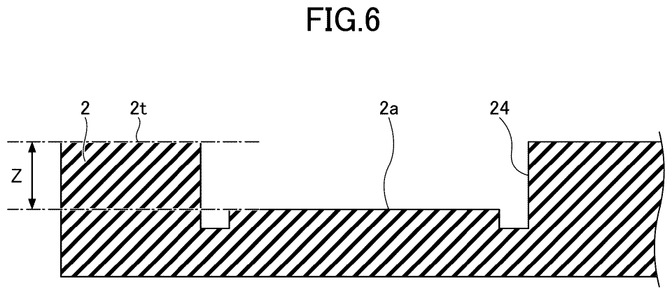

A film forming apparatus 100 according to an embodiment will be described with reference to FIGS. 1 to 6. FIG. 1 is a cross-sectional view showing an example of the configuration of the film forming apparatus 100 according to an embodiment. FIG. 2 is an oblique view showing the configuration of the interior of a vacuum container 1 of the film forming apparatus 100 according to the embodiment. FIG. 3 is a plan view showing the configuration of the interior of the vacuum container 1 of the film forming apparatus 100 according to the embodiment. In FIGS. 2 and 3, a top plate 11 is not shown. FIG. 4 is a cross-sectional view showing a part of the film forming apparatus 100 according to the embodiment. FIG. 5 is a cross-sectional view showing another part of the film forming apparatus 100 according to the embodiment. FIG. 6 is a cross-sectional view showing a part of a susceptor 2 included in the film forming apparatus 100 according to the embodiment. As shown in FIGS. 1 to 3, the film forming apparatus 100 includes a vacuum container 1 and a susceptor 2.

The vacuum container 1 has a substantially circular planar shape. The vacuum container 1 includes the top plate 11 and a container body 12. The top plate 11 is airtightly detachably-attachably situated on the upper surface of the container body 12 via a sealing member 13, such as an O-ring and the like. The container body 12 has a bottomed cylindrical shape.

The susceptor 2 is provided in the vacuum container 1. The susceptor 2 has a center of rotation on the center of the vacuum container 1. The susceptor 2 is formed of, for example, quartz. The susceptor 2 is fixed to a cylindrical core 21 at its center. The core 21 is fixed to the upper end of a rotary shaft 22. The rotary shaft 22 extends in the vertical direction. The rotary shaft 22 penetrates a bottom 14 of the vacuum container 1. The lower end of the rotary shaft 22 is attached to a driver 23. The driver 23 rotates the rotary shaft 22 about a vertical axis. The rotary shaft 22 and the driver 23 are housed in a case body 20. The case body 20 has a cylindrical shape with an open upper surface. A flange of the case body 20, which is provided on the upper surface the case body 20, is airtightly attached to the lower surface of the bottom 14 of the vacuum container 1. Thus, an airtight state between the internal atmosphere and the external atmosphere of the case body 20 is maintained.

On the upper surface of the susceptor 2, a plurality of (e.g., six) recesses 24 are provided along the rotational direction (circumferential direction). Each recess 24 has a circular shape. A substrate W is placed in each recess 24. The substrate W is, for example, a semiconductor wafer. FIG. 3 shows the substrate W in only one recess 24 for the sake of convenience. Each recess 24 is provided at a position that is offset from the rotary shaft 22 of the susceptor 2 in the horizontal direction. Each recess 24 has an inner diameter slightly greater, for example, by 4 mm than the diameter of the substrate W and a depth substantially equal to the thickness of the substrate W. Therefore, when the substrate W is accommodated in the recess 24, the surface of the substrate W and the surface of the susceptor 2 (the region where the substrate W is not placed) are at the same height. The bottom surface of each recess 24 is a mounting surface 2a (FIG. 6) on which the substrate W is mounted. Through-holes (not shown) are provided in the bottom surface of the recess 24. A plurality of (for example, three) elevation pins for moving up or down the substrate W while supporting the back surface of the substrate W penetrate the through-holes.

Above the susceptor 2, processing gas nozzles 31 and 32, a cleaning gas nozzle 33 and separation gas nozzles 41 and 42 are situated at intervals from each other in the circumferential direction of the vacuum container 1 (the rotational direction of the susceptor 2 shown by an arrow A in FIG. 3). In the illustrated example, the separation gas nozzle 41, the cleaning gas nozzle 33, the processing gas nozzle 31, the separation gas nozzle 42, and the processing gas nozzle 32 are situated in this order in the clockwise direction (the rotational direction of the susceptor 2) from a conveying port 15 described later. Gas introduction ports 31a, 32a, 33a, 41a, and 42a (FIG. 3), which are the base ends of the processing gas nozzles 31 and 32, the cleaning gas nozzle 33, and the separation gas nozzles 41 and 42, are fixed to the outer circumferential wall of the container body 12. The processing gas nozzles 31 and 32, the cleaning gas nozzle 33, and the separation gas nozzles 41 and 42 are introduced into the vacuum container 1 from the outer circumferential wall of the vacuum container 1 and are attached so as to extend horizontally to the susceptor 2 along the radial direction of the container body 12. The processing gas nozzles 31 and 32, the cleaning gas nozzle 33, and the separation gas nozzles 41 and 42 are formed of, for example, quartz.

The processing gas nozzle 31 is connected to a raw material gas supply source (not shown) via a pipe, a flow rate controller, and the like (not shown). The raw material gas is, for example, a silicon-containing gas. The raw material gas may be a metal-containing gas. The processing gas nozzle 32 is connected to a reaction gas supply source (not shown) via a pipe, a flow rate controller, and the like (not shown). The reaction gas is a gas that reacts with the raw material gas to produce a reaction product. The reaction gas is, for example, an oxidizing gas. The reaction gas may be a nitriding gas.

The cleaning gas nozzle 33 is connected to a cleaning gas supply source (not shown) via a pipe, a flow rate controller, and the like (not shown). The cleaning gas nozzle 33 is an example of a gas supply. The cleaning gas is a gas capable of removing the reaction product produced from the reaction between the raw material gas and the reaction gas. The cleaning gas is selected in accordance with the types of the raw material gas and the reaction gas. The cleaning gas may be a halogen-containing gas. The cleaning gas may be a fluorine-containing gas, such as chlorine trifluoride (ClF₃), nitrogen trifluoride (NF₃), and the like. The cleaning gas may be a chlorine-containing gas, a bromine-containing gas, or an iodine-containing gas.

The separation gas nozzles 41 and 42 are connected to a separation gas supply source (not shown) via a pipe, a flow rate control valve, and the like (not shown). The separation gas may be an inert gas. The separation gas may be, for example, argon (Ar). The separation gas may be nitrogen (N₂).

In the processing gas nozzles 31 and 32, a plurality of discharge holes 31h and 32h (FIG. 4) opening toward the susceptor 2 are arranged along the direction of the length of the processing gas nozzles 31 and 32 at intervals of, for example, 10 mm. The region under the processing gas nozzle 31 is an adsorption region P1 for adsorbing the raw material gas to the substrate W. The region under the processing gas nozzle 32 is a reaction region P2 for causing the raw material gas adsorbed to the substrate W in the adsorption region P1 to react with the reaction gas

As shown in FIGS. 2 and 3, two protrusions 4 are provided in the vacuum container 1. The protrusions 4 constitute separation regions D together with the separation gas nozzles 41 and 42. Therefore, as described later, the protrusions 4 are attached to the back surface of the top plate 11 so as to protrude toward the susceptor 2. The protrusions 4 each have a fan-shaped planar shape with the top part cut in an arc shape. The protrusions 4 are each situated such that an inner arc of each protrusion 4 is joined to a projection 5 (described later) and an outer arc of each protrusion 4 is along the inner circumferential surface of the container body 12 of the vacuum container 1.

FIG. 4 shows a cross-section of the vacuum container 1 along a concentric circle of the susceptor 2 from the processing gas nozzle 31 to the processing gas nozzle 32. As shown in FIG. 4, the protrusion 4 is attached to the back surface of the top plate 11. Therefore, in the vacuum container 1, there are a flat, low ceiling surface (first ceiling surface 44) that is the lower surface of the protrusion 4, and a ceiling surface (second ceiling surface 45) that is located on both sides of the first ceiling surfaces 44 in the circumferential direction and is higher than the first ceiling surface 44. The first ceiling surface 44 have a fan-shaped planar shape with the top part cut in an arc shape. In the protrusion 4, a groove 43 is formed at the circumferential-direction center so as to extend in the radial direction. The separation gas nozzle 42 is accommodated in the groove 43. The groove 43 is similarly formed in the other protrusion 4, where the separation gas nozzle 41 is accommodated in the groove 43. The processing gas nozzles 31 and 32 are provided in the spaces under the second ceiling surface 45, respectively. The processing gas nozzles 31 and 32 are provided apart from the second ceiling surface 45 to become close to the substrate W. As shown in FIG. 4, the processing gas nozzle 31 is provided in a space 481 under the second ceiling surface 45 on the right side of the protrusion 4, and the processing gas nozzle 32 is provided in a space 482 under the second ceiling surface 45 on the left side.

The separation gas nozzle 42 is provided with a plurality of discharge holes 42h opening toward the susceptor 2. The plurality of discharge holes 42h are arranged at intervals of, for example, 10 mm along the direction of the length of the separation gas nozzle 42. Similarly to the separation gas nozzle 42, a plurality of discharge holes (not shown) are arranged in the separation gas nozzle 41.

The first ceiling surface 44 forms a separation space H, which is a narrow space, with respect to the susceptor 2. When the separation gas is supplied from the discharge holes 42h of the separation gas nozzle 42, the separation gas flows through the separation space H toward the spaces 481 and 482. Here, since the volume of the separation space H is smaller than the volume of the spaces 481 and 482, the separation gas can make the pressure in the separation space H higher than the pressures in the spaces 481 and 482. That is, the separation space H having a high pressure is formed between the spaces 481 and 482. The separation gas flowing out from the separation space H into the spaces 481 and 482 acts as a counterflow to the raw material gas from the adsorption region P1 and to the reaction gas from the reaction region P2. Therefore, the raw material gas supplied to the adsorption region P1 and the reaction gas supplied to the reaction region P2 are separated by the separation space H. Therefore, it is possible to reduce the reaction between the raw material gas and the reaction gas due to their being mixed in the vacuum container 1.

A height h1 of the first ceiling surface 44 with respect to the upper surface of the susceptor 2 is set to a height suitable for making the pressure in the separation space H higher than the pressures in the spaces 481 and 482 in consideration of the pressure in the vacuum container 1 during film formation, the rotational speed of the susceptor 2, the flow rate of the separation gas, and the like.

The lower surface of the top plate 11 is provided with the projection 5 surrounding the outer circumference of the core 21 to which the susceptor 2 is fixed. The projection 5 is continuous with a part of the protrusion 4 on the center-of-rotation side, and the lower surface of the projection 5 is formed at the same height as the first ceiling surface 44.

FIG. 1, which has been referred to above, is a cross-sectional view taken along a line I-I′ of FIG. 3, and shows a region in which the second ceiling surface 45 is provided. On the other hand, FIG. 5 shows a region in which the first ceiling surface 44 is provided. As shown in FIG. 5, a bent part 46 bending in a letter-L shape so as to face the outer end surface of the susceptor 2 is formed on the circumferential edge of the fan-shaped protrusion 4 (which is a part on the side of the outer border of the vacuum container 1). Similarly to the protrusion 4, the bent part 46 reduces the intrusion of the raw material gas and the reaction gas from both sides of the separation region D, and reduces the mixing of the raw material gas and the reaction gas. The protrusion 4 is provided on the top plate 11, and there is a slight gap between the outer circumferential surface of the bent part 46 and the container body 12 because the top plate 11 can be detached from the container body 12. The gap between the inner circumferential surface of the bent part 46 and the outer end surface of the susceptor 2 and the gap between the outer circumferential surface of the bent part 46 and the container body 12 are set to the same dimension as, for example, the height of the first ceiling surface 44 with respect to the upper surface of the susceptor 2.

In the separation regions D, the inner circumferential wall of the container body 12 is formed in a vertical plane shape close to the outer circumferential surface of the bent part 46 (FIG. 5), whereas in the regions other than the separation regions D, the inner circumferential wall of the container body 12 is dented outward for a length extending from the part facing the outer end surface of the susceptor 2 to the bottom 14 (FIG. 1). Hereinafter, for convenience of explanation, the dented part having a roughly rectangular cross-sectional shape is referred to as a gas exhaust region E. Specifically, the gas exhaust region communicating with the adsorption region P1 is referred to as a first gas exhaust region E1, and the region communicating with the reaction region P2 is referred to as a second gas exhaust region E2. As shown in FIGS. 1 to 3, a first gas exhaust port 61 and a second gas exhaust port 62 are formed at the bottom of the first gas exhaust region E1 and the second gas exhaust region E2, respectively. As shown in FIG. 1, the first gas exhaust port 61 and the second gas exhaust port 62 are each connected to a vacuum gas exhaust part, which is, for example, a vacuum pump 64, via a gas exhaust pipe 63. Th gas exhaust pipe 63 is provided with a pressure controller 65 so as to be able to adjust the pressure in the vacuum container 1.

As shown in FIGS. 1 and 5, a heater unit 7 is provided in a space between the susceptor 2 and the bottom 14 of the vacuum container 1. The heater unit 7 heats the substrate W on the susceptor 2 to a temperature specified in a process recipe by radiation.

An annular cover member 71 is provided under the circumferential edge of the susceptor 2 (FIG. 5). The cover member 71 partitions the atmosphere in a region extending from the space above the susceptor 2 to the first gas exhaust region E1 and the second gas exhaust region E2 and the atmosphere in which the heater unit 7 is placed from each other to reduce the intrusion of gas into the region under the susceptor 2. The cover member 71 includes an inner member 71a and an outer member 71b. The inner member 71a is provided so as to face the outer edge of the susceptor 2 and a more outward circumferential side of the outer edge from under them. The inner member 71a surrounds the entire circumference of the heater unit 7 while being under the outer edge of the susceptor 2 (and under the portion slightly on the outer side of the outer edge). The outer member 71b is provided between the inner member 71a and the inner circumferential surface of the vacuum container 1. In the separation region D, the outer member 71b is provided under the bent part 46 formed on the outer edge of the protrusion 4 closely to the bent part 46.

A part of the bottom 14 that is on the center-of-rotation side of the space in which the heater unit 7 is situated protrudes upward so as to be close to the core 21 that is near the center of the lower surface of the susceptor 2 to form a projection 12a. The space between the projection 12a and the core 21 is narrow, and the gap between the inner circumferential surface of the through-hole in which the rotary shaft 22 penetrates the bottom 14 and the rotary shaft 22 is narrow. These narrow spaces communicate with the case body 20. The case body 20 is provided with a purge gas supply pipe 72. The purge gas supply pipe 72 supplies a purge gas into the narrow spaces and purges the atmosphere therein. The purge gas is, for example, the same gas as the separation gas. A plurality of purge gas supply pipes 73 are provided in the bottom 14 of the vacuum container 1. The plurality of purge gas supply pipes 73 are provided at predetermined angular intervals in the circumferential direction under the heater unit 7. The plurality of purge gas supply pipes 73 supply a purge gas into the space in which the heater unit 7 is situated to purge the atmosphere therein. A cap member 7a is provided between the heater unit 7 and the susceptor 2. The cap member 7a covers the region extending from the inner circumferential wall of the outer member 71b (or the upper surface of the inner member 71a) to the upper end of the projection 12a by extending along in the circumferential direction. Thus, the intrusion of gas into the region in which the heater unit 7 is provided is reduced. The cap member 7a is formed of, for example, quartz.

A separation gas supply pipe 51 is connected to the center of the top plate 11 of the vacuum container 1. The separation gas supply pipe 51 supplies the separation gas into a space 52 between the top plate 11 and the core 21. The separation gas supplied into the space 52 is discharged toward the circumferential edge of the susceptor 2 along the surface of the susceptor 2 on the wafer mounting region side through a narrow gap 50 between the projection 5 and the susceptor 2. The gap 50 can be maintained at a higher pressure than in the spaces 481 and 482 by the separation gas. The gap 50 reduces the mixing of the raw material gas supplied into the adsorption region P1 and the reaction gas supplied into the reaction region P2 through the center region C. That is, the gap 50 (or the center region C) functions similarly to the separation space H (or the separation region D).

As shown in FIGS. 2 and 3, the side wall of the vacuum container 1 is provided with the conveying port 15 in order for an external conveying arm 10 and the susceptor 2 to transfer the substrate W between the external conveying arm 10 and the susceptor 2. The conveying port 15 is opened or closed by a gate valve (not shown). Under the susceptor 2, the elevation pins for pass-over and take-over, which penetrate the recess 24 for elevating the substrate W by the back surface of the substrate W, and a mechanism for elevating the elevation pins (both not shown) are provided at a part corresponding to the position at which the substrate W is transferred.

The film forming apparatus 100 includes a height measuring part 8. The height measuring part 8 measures the height of the upper surface 2t of the susceptor 2 and the height of the mounting surface 2a of the recess 24. The substrate W is mounted on the mounting surface 2a. The height measuring part 8 sends each measured height to a controller 9. The height measuring part 8 is, for example, a laser displacement meter. The height measuring part 8 may be a camera.

The film forming apparatus 100 includes the controller 9. The controller 9 is an electronic circuit, such as a Central Processing Unit (CPU), a Field Programmable Gate Array (FPGA), an Application Specific Integrated Circuit (ASIC). The controller 9 executes various control operations described herein by executing an instruction code stored in a memory or by being designed as a circuit for a specific application.

The controller 9 calculates the depth Z of the recess 24 by subtracting the height of the mounting surface 2a of the recess 24 from the height of the upper surface 2t of the susceptor 2 measured by the height measuring part 8.

### [Method of Operating Film Forming Apparatus]

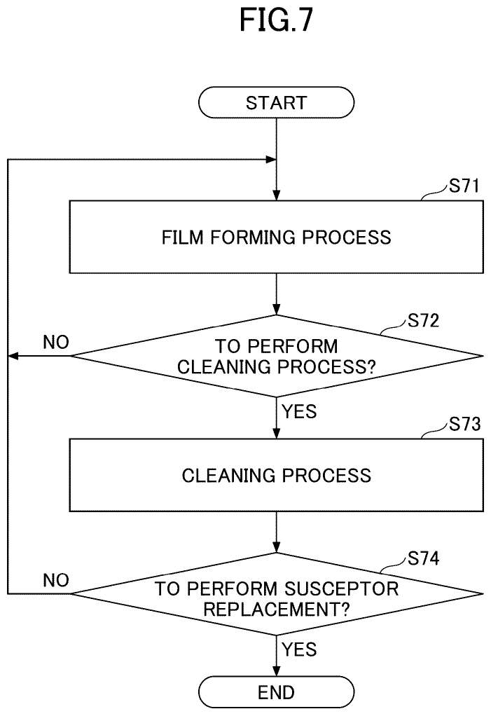

An example of a method of operating the film forming apparatus 100 according to the embodiment will be described with reference to FIG. 7. FIG. 7 is a flowchart showing an example of the method of operating the film forming apparatus 100 according to the embodiment. The method of operating the film forming apparatus 100 according to the embodiment is performed under the control of the controller 9. The method of operating the film forming apparatus 100 according to the embodiment includes steps S71 through S74 of FIG. 7.

In step S71, the controller 9 controls each part of the film forming apparatus 100 such that a film forming process is performed in the film forming apparatus 100. The film forming process includes mounting the substrate W on the mounting surface 2a of each recess 24 of the susceptor 2 and supplying the raw material gas from the processing gas nozzle 31 and supplying the reaction gas from the processing gas nozzle 32 to thereby deposit a film on the substrate W mounted on the mounting surface 2a. In the film forming process, almost no film is deposited on the mounting surface 2a, whereas a film is deposited on the upper surface 2t of the susceptor 2. This is because during the film forming process, the mounting surface 2a is covered with the substrate W, whereas the upper surface 2t of the susceptor 2 is not covered with the substrate W. The film is, for example, a silicon oxide film.

Step S72 is performed after step S71. In step S72, the controller 9 determines whether or not to perform a cleaning process in the film forming apparatus 100. Whether or not to perform the cleaning process is determined based on, for example, whether or not the number of times the film forming process of step S71 has been performed has reached a set number of times. The set number of times is, for example, two or more times. The set number of times may be one. When determining in step S72 to perform the cleaning process (YES in step S72), the controller 9 moves the flow to step S73. When determining in step S72 to not perform the cleaning process (NO in step S72), the controller 9 returns the flow to step S71.

Step S73 is performed after step S72. In step S73, the controller 9 controls each part of the film forming apparatus 100 to perform the cleaning process in the film forming apparatus 100. The cleaning process includes supplying the cleaning gas into the vacuum container 1 and removing a film deposited on the upper surface 2t of the susceptor 2 by etching. The cleaning gas is a gas that can remove the film by etching. For example, when removing a silicon oxide film, the cleaning gas is, for example, chlorine trifluoride and nitrogen trifluoride. The cleaning process includes a first cleaning process and a second cleaning process. The first cleaning process includes supplying the cleaning gas to the susceptor 2 with a protective member 120 not present on the mounting surface 2a, and removing the film formed on the upper surface 2t of the susceptor 2.

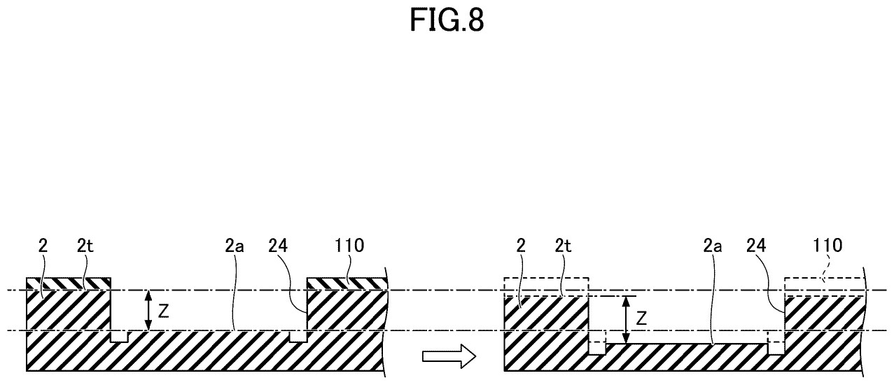

FIG. 8 is a diagram showing change in the depth Z of the recess 24 between before and after the first cleaning process. The left view of FIG. 8 shows a cross-section of a part of the susceptor 2 before the first cleaning process is performed, and the right view of FIG. 8 shows a cross-section of the part of the susceptor 2 after the first cleaning process is performed. In the right view of FIG. 8, a film 110 removed by etching and the susceptor 2 removed by etching are shown by broken lines.

When the cleaning gas is supplied to the susceptor 2 with the protective member 120 not present on the mounting surface 2a as shown in the left view of FIG. 8, the depth Z of the recess 24 increases as shown in the right view of FIG. 8. It is considered that this is because the amount by which the susceptor 2 is etched from the upper surface 2t of the susceptor 2 is small because there is the film 110 there, whereas the amount by which the susceptor 2 is etched from the mounting surface 2a is large because there is no film 110 there.

The second cleaning process includes supplying the cleaning gas to the susceptor 2 with the protective member 120 mounted on the mounting surface 2a, and removing the film formed on the upper surface 2t of the susceptor 2. It is preferable that the protective member 120 has a planar shape and a size similar to those of the substrate W, more preferably has a planar shape and a size substantially the same as those of the substrate W, and most preferably has a planar shape and a size the same as those of the substrate W.

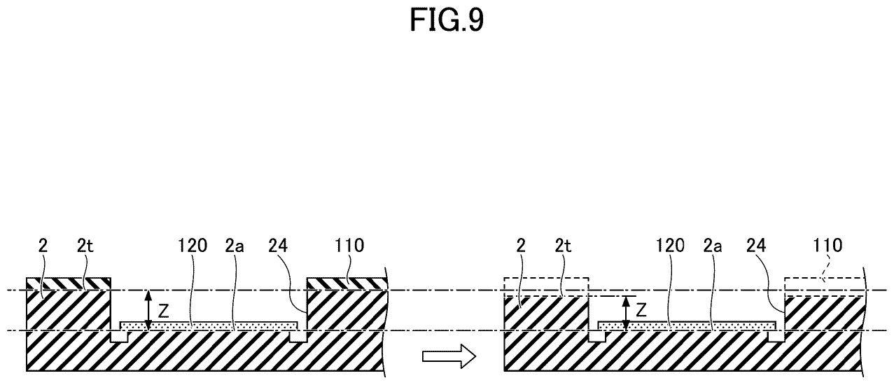

FIG. 9 is a diagram showing change in the depth Z of the recess 24 between before and after the second cleaning process. The left view of FIG. 9 shows a cross-section of a part of the susceptor 2 before the second cleaning process is performed, and the right view of FIG. 9 shows a cross-section of the part of the susceptor 2 after the second cleaning process is performed. In the right view of FIG. 9, the film 110 removed by etching and the susceptor 2 removed by etching are shown by broken lines.

When the cleaning gas is supplied to the susceptor 2 with the protective member 120 present on the mounting surface 2a as shown in the left view of FIG. 9, the depth Z of the recess 24 decreases as shown in the right view of FIG. 9. It is considered that this is because not only the film 110 present on the upper surface 2t of the susceptor 2 but also the upper surface 2t is slightly etched as well after the film 110 is removed, whereas the mounting surface 2a is almost not etched because it is covered with the protective member 120.

In the method of operating the film forming apparatus 100 according to the embodiment, for example, the second cleaning process is performed after the first cleaning process has been performed a first number of times. Although the depth Z of the recess 24 increases as the first cleaning process is repeated, the depth Z of the recess 24 decreases as the second cleaning process is repeated after the first number of times has been reached. Therefore, the amount of increase and the amount of decrease in the depth Z of the recess 24 can be balanced, and the amount of change in the depth Z of the recess 24 can be reduced.

The first number of times is determined based on, for example, a first amount of change in the depth Z of the recess 24 when the first cleaning process is performed once. The first amount of change is a value previously determined by, for example, an experiment or the like. The first amount of change may be a value calculated by the controller 9 based on values measured by the height measuring part 8 after the first cleaning process is performed.

The first number of times is determined such that, for example, the value obtained by adding a first product obtained by multiplying the first amount of change by the first number of times to the initial value of the depth Z of the recess 24 becomes less than the upper limit value of the depth Z of the recess 24. When the depth Z of the recess 24 increases excessively, the step between the upper surface of the substrate W mounted on the mounting surface 2a and the upper surface 2t of the susceptor 2 increases. As a result, gas accumulation or the like occurs near the upper surface of the substrate W, and the uniformity of the film to be deposited on the substrate W in the film forming process may deteriorate. Therefore, it is preferable to set the upper limit value of the depth Z of the recess 24 to a value that does not or almost does not affect the uniformity of the film to be deposited on the substrate W in the film forming process.

As an example, when the first amount of change is 0.1 mm, the initial value of the depth Z of the recess 24 is Z1, and the upper limit value of the depth Z of the recess 24 is Z1+0.51 mm, the first number of times is determined to be five or less.

In the method of operating the film forming apparatus 100 according to the embodiment, for example, the first cleaning process is performed after the second cleaning process has been performed a second number of times. As the second cleaning process is repeated, the depth Z of the recess 24 decreases, whereas as the first cleaning process is repeated after the second number of times has been reached, the depth Z of the recess 24 increases. Therefore, the amount of increase and the amount of decrease in the depth Z of the recess 24 can be balanced, and the amount of change in the depth Z of the recess 24 can be reduced.

The second number of times is determined based on, for example, a second amount of change in the depth Z of the recess 24 when the second cleaning process is performed once. The second amount of change is a value previously determined by, for example, an experiment or the like. The second amount of change may be a value calculated by the controller 9 based on values measured by the height measuring part 8 after the second cleaning process is performed.

The second number of times is determined such that, for example, the value obtained by subtracting a second product obtained by multiplying the second amount of change by the second number of times from the initial value of the depth Z of the recess 24 becomes greater than the lower limit value of the depth Z of the recess 24. When the depth Z of the recess 24 decreases excessively, the step between the upper surface of the substrate W mounted on the mounting surface 2a and the upper surface 2t of the susceptor 2 increases. As a result, gas accumulation or the like occurs near the upper surface of the substrate W, and the uniformity of the film to be deposited on the substrate W in the film forming process may deteriorate. Therefore, it is preferable to set the lower limit value of the depth Z of the recess 24 to a value that does not or almost does not affect the uniformity of the film to be deposited on the substrate W in the film forming process. When the depth Z of the recess 24 decreases excessively, the substrate W mounted on the mounting surface 2a may protrude from the recess 24. Therefore, it is preferable to set the lower limit value of the depth Z of the recess 24 to a value at which the substrate W mounted on the mounting surface 2a does not protrude from the recess 24.

As an example, when the second amount of change is 0.05 mm, the initial value of the depth Z of the recess 24 is Z1, and the lower limit value of the depth Z of the recess 24 is Z1−0.31 mm, the second number of times is set to six or less.

The cleaning process may include repeating: performing the second cleaning process after the first cleaning process has been performed the first number of times; and performing the first cleaning process after the second cleaning process has been performed the second number of times. In this case, it is possible to maintain the depth Z of the recess 24 within a desired range, for example, within a range between the lower limit value and the upper limit value.

The cleaning process may include setting the first number of times and the second number of times such that the relationship of n*X=m*Y is satisfied, where X represents the first amount of change, Y represents the second amount of change, n represents the first number of times, and m represents the second number of times. In this case, the depth Z of the recess 24 after the first cleaning process has been performed the first number of times and the second cleaning process has been performed the second number of times can be maintained as the initial state.

The cleaning process may include setting the first number of times to A2 and the second number of times to A1 when the ratio of the first amount of change to the second amount of change is A1:A2 (where A1 and A2 are natural numbers). As an example, when the ratio of the first amount of change to the second amount of change is 2:1, the first number of times may be set to 1 and the second number of times may be set to 2.

In the cleaning process, the timing to switch between the first cleaning process and the second cleaning process is, for example, the same for all the recesses 24. In the cleaning process, the timing to switch between the first cleaning process and the second cleaning process may be varied for each of the recesses 24.

Step S74 is performed after step S73. In step S74, the controller 9 determines whether or not to perform susceptor replacement. Whether or not to perform susceptor replacement is determined based on, for example, whether or not the number of times the cleaning process of step S73 has been performed has reached the set number of times. The set number of times is, for example, 2 or greater. The set number of times may be 1. When determining in step S74 to perform susceptor replacement (YES in step S74), the controller 9 ends the flow. When determining in step S74 to not perform susceptor replacement (NO in step S74), the controller 9 returns the flow to step S71.

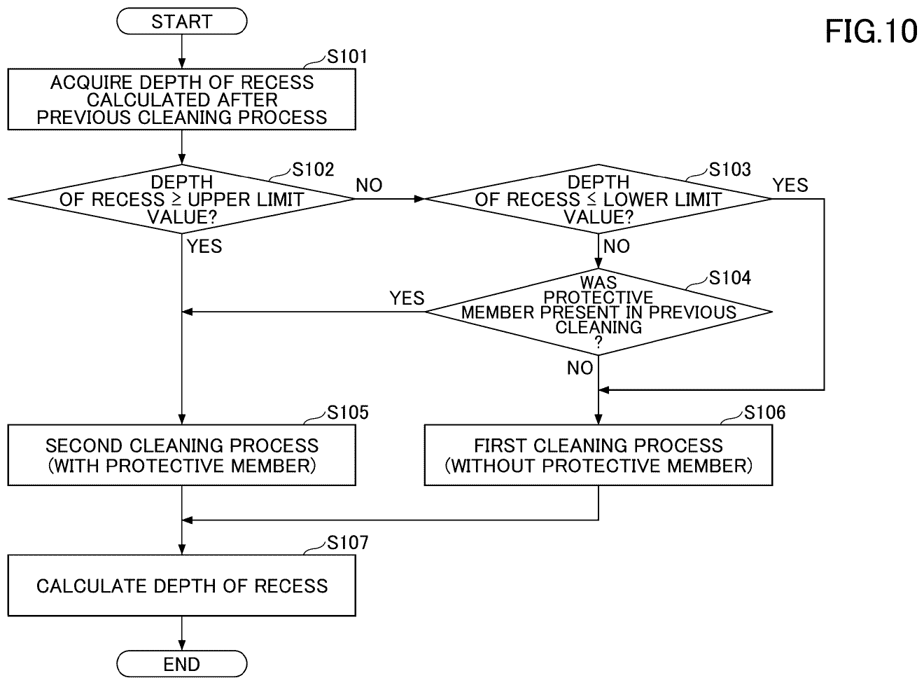

An example of the cleaning process will be described with reference to FIG. 10. FIG. 10 is a flowchart showing an example of the cleaning process. In the process shown in FIG. 10, the controller 9 calculates the depth Z of the recess 24 based on values measured by the height measuring part 8 every time the cleaning process is performed once, and switches between the first cleaning process and the second cleaning process based on the calculated depth Z of the recess 24. The process shown in FIG. 10 is performed under the control of the controller 9. The process shown in FIG. 10 includes steps S101 to S107.

In step S101, the controller 9 acquires the depth Z of the recess 24 calculated after the previous cleaning process.

In step S102, the controller 9 determines whether or not the depth Z of the recess 24 is equal to or greater than the upper limit value. When determining in step S102 that the depth Z of the recess 24 is equal to or greater than the upper limit value (YES in step S102), the controller 9 moves the flow to step S105. When determining in step S102 that the depth Z of the recess 24 is not equal to or greater than the upper limit value (NO in step S102), the controller 9 moves the flow to step S103.

In step S103, the controller 9 determines whether or not the depth Z of the recess 24 is equal to or less than the lower limit value. When determining in step S103 that the depth Z of the recess 24 is equal to or less than the lower limit value (YES in step S103), the controller 9 moves the flow to step S106. When determining in step S103 that the depth Z of the recess 24 is not equal to or less than the lower limit value (NO in step S103), the controller 9 moves the flow to step S104.

In step S104, the controller 9 determines whether or not the previous cleaning process was performed with the protective member 120 mounted on the mounting surface 2a. When determining in step S104 that the cleaning process was performed with the protective member 120 mounted on the mounting surface 2a (YES in step S104), the controller 9 moves the flow to step S105. When determining in step S104 that the cleaning process was performed with the protective member 120 not mounted on the mounting surface 2a (NO in step S104), the controller 9 moves the flow to step S106.

In step S105, the controller 9 controls each part of the film forming apparatus 100 to perform the cleaning process with the protective member 120 mounted on the mounting surface 2a. That is, the controller 9 controls each part of the film forming apparatus 100 to perform the second cleaning process.

In step S106, the controller 9 controls each part of the film forming apparatus 100 to perform the cleaning process with the protective member 120 not mounted on the mounting surface 2a. That is, the controller 9 controls each part of the film forming apparatus 100 to perform the first cleaning process.

In step S107, the height measuring part 8 measures the height of the upper surface 2t of the susceptor 2 and the height of the mounting surface 2a, and the controller 9 calculates the depth Z of the recess 24 based on the values measured by the height measuring part 8. The controller 9 may store the calculated depth Z of the recess 24 in a storage unit. In the way described above, one cleaning process is performed.

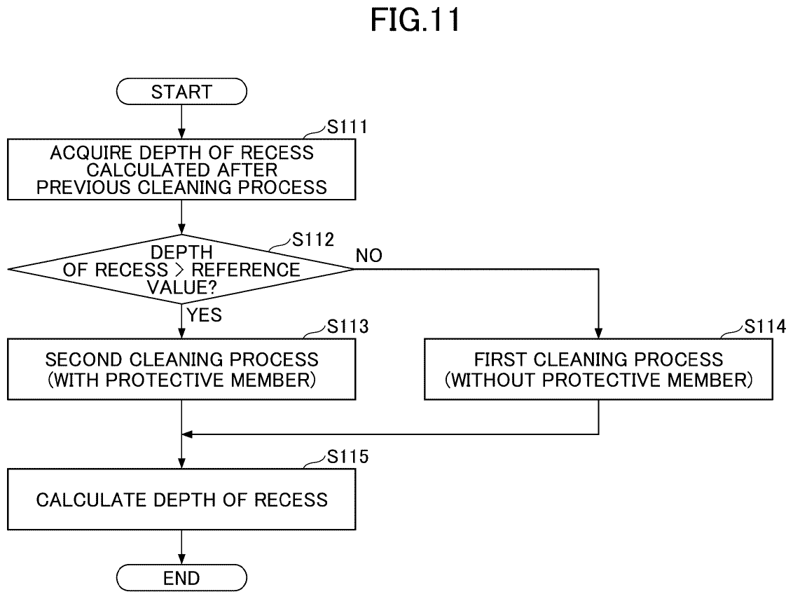

Another example of the cleaning process of FIG. 7 will be described with reference to FIG. 11. FIG. 11 is a flowchart showing another example of the cleaning process. In the process shown in FIG. 11, the controller 9 calculates the depth Z of the recess 24 based on values measured by the height measuring part 8 every time the cleaning process is performed once, and switches between the first cleaning process and the second cleaning process based on the calculated depth Z of the recess 24. The process shown in FIG. 11 is performed under the control of the controller 9. The process shown in FIG. 11 includes steps S111 to S115.

In step S111, the controller 9 acquires the depth Z of the recess 24 calculated after the previous cleaning process.

In step S112, the controller 9 determines whether or not the depth Z of the recess 24 is greater than a reference value. When determining in step S112 that the depth Z of the recess 24 is greater than the reference value (YES in step S112), the controller 9 moves the flow to step S113. When determining in step S112 that the depth Z of the recess 24 is not greater than the reference value (NO in step S112), the controller 9 moves the flow to step S114.

In step S113, the controller 9 controls each part of the film forming apparatus 100 to perform the cleaning process with the protective member 120 mounted on the mounting surface 2a. That is, the controller 9 controls each part of the film forming apparatus 100 to perform the second cleaning process.

In step S114, the controller 9 controls each part of the film forming apparatus 100 to perform the cleaning process with the protective member 120 not mounted on the mounting surface 2a. That is, the controller 9 controls each part of the film forming apparatus 100 to perform the first cleaning process. In step S115, the height measuring part 8 measures the height of the upper surface 2t of the susceptor 2 and the height of the mounting surface 2a, and the controller 9 calculates the depth Z of the recess 24 based on the values measured by the height measuring part 8. In the way described above, one cleaning process is performed.

The embodiments disclosed herein should be considered exemplary in all respects and not restrictive. Various omissions, replacements, and modifications are applicable to the above embodiments without departing from the scope and spirit of the appended claims.

According to the present disclosure, it is possible to reduce the amount of change in the depth from the upper surface of a susceptor to the mounting surface.

What is claimed is:

1. A method of operating a film forming apparatus including a susceptor having a recess on a surface of the susceptor, the recess in which a substrate is mounted, the method comprising:
(a) removing a film formed on the surface of the susceptor by supplying a cleaning gas to the susceptor with a protective member not mounted on the recess; and
(b) removing the film formed on the surface of the susceptor by supplying the cleaning gas to the susceptor with the protective member mounted on the recess,
wherein the (b) removing is performed after the (a) removing has been performed a first number of times.

2. The method of operating the film forming apparatus according to claim 1,
wherein the first number of times is determined based on a first amount of change in a depth of the recess when the (a) removing has been performed once.

3. The method of operating the film forming apparatus according to claim 2,
wherein the first amount of change is a previously determined value.

4. The method of operating the film forming apparatus according to claim 2,
wherein the first amount of change is calculated based on a value measured after the (a) removing has been performed.

5. The method for operating the film forming apparatus according to claim 1,
wherein the (a) removing is performed after the (b) removing has been performed a second number of times.

6. The method of operating the film forming apparatus according to claim 5,
wherein the second number of times is determined based on a second amount of change in a depth of the recess when the (b) removing has been performed once.

7. The method of operating the film forming apparatus according to claim 6,
wherein the second amount of change is a previously determined value.

8. The method of operating the film forming apparatus according to claim 6,
wherein the second amount of change is calculated based on a value measured after the (b) removing has been performed.

9. The method of operating the film forming apparatus according to claim 1,
wherein a plurality of recesses, each of which is the recess, are provided along a circumferential direction of the susceptor.

10. The method of operating the film forming apparatus according to claim 9,
wherein a timing to switch between the (a) removing and the (b) removing is the same for all of the plurality of recesses.

11. The method of operating the film forming apparatus according to claim 9,
wherein a timing to switch the (a) removing and the (b) removing is varied for each of the plurality of recesses.

12. A film forming apparatus, comprising:
a vacuum container;
a susceptor provided in the vacuum container and having a recess on a surface thereof, the recess in which a substrate is mounted;
a gas supply configured to supply a cleaning gas to the susceptor; and
a controller;
wherein the controller is configured to perform:
(a) removing a film formed on the surface of the susceptor by supplying the cleaning gas to the susceptor with a protective member not mounted on the recess; and
(b) removing the film formed on the surface of the susceptor by supplying the cleaning gas to the susceptor with the protective member mounted on the recess, and
wherein the (b) removing is performed after the (a) removing has been performed a first number of times.
